(19) United States
(12) Patent Application Publication
(10) Pub. No.: US 2014/0306303 A1
(43) Pub. Date: Oct. 16, 2014

(54) Seed Layer for Perpendicular Magnetic Anisotropy (PMA) Thin Film

(71) Applicant: Headway Technologies, Inc., Milpitas, CA (US)

(72) Inventors: Takahiro Moriyama, Osaka (JP); Yu-Jen Wang, San Jose, CA (US); Ru-Ying Tong, Los Gatos, CA (US)

(21) Appl. No.: 13/863,545

(22) Filed: Apr. 16, 2013

(51) Int. Cl. H01L 43/10; H01L 43/12

(52) U.S. Cl. CPC H01L 43/10; H01L 43/12
USPC 257/421; 438/3; 428/832; 428/831.2; 428/832.1; 428/832.3

(57) ABSTRACT

A magnetic thin film deposition having PMA (perpendicular magnetic anisotropy) is a multilayered fabrication of materials having differing crystal symmetries that smoothly transition by use of a seed layer that promotes symmetry matching. An interface between layers in the deposition, such as an interface between a layer of MgO and an Fe-containing ferromagnetic layer, is a source of perpendicular magnetic anisotropy which then propagates throughout the remainder of the deposition by means of the symmetry matching seed layer.

### BACKGROUND

1. Technical Field

This disclosure relates generally to magnetic devices that utilize thin film magnetic layers with perpendicular magnetic anisotropy (PMA), and more specifically, to seed layers for enhancing the PMA properties of such devices.

2. Description of the Related Art

Many present day magnetic devices utilize thin film depositions in which magnetic thin films may have in-plane (plane of deposition) magnetization directions, out-of-plane (i.e., perpendicular to the film plane) magnetization directions, which is often referred to as perpendicular magnetic anisotropy (PMA) or even components in both of such directions. Such devices include, but are not limited to:
(1) various designs of magnetic random access memory (MRAM), e.g., PMA (or Partial-PMA) Spin-Torque MRAM in which such films can serve as pinned layers, reference layers, free layers, or dipole (offset-compensation) layers;
(2) various designs of PMA spin valves, tunnel valves (magnetic tunnel junctions—MTJs) and PMA media used in magnetic sensors and magnetic data storage, and;
(3) other spintronic devices.

PMA layers are used in these devices for a variety of reasons. In spin-torque MRAMs, for example, the PMA layers, among other advantages, provide better functionality, better thermal stability and a reduction of switching currents.

The source of the PMA can either come from the bulk properties of the chosen materials or it can originate in the interface between the layers. To achieve better control of the PMA, multilayers that include at least one ferromagnetic material are commonly used.

One of these multilayers is the Co/Ni multilayer system. The PMA in this system arises from electronic band matching at the FCC (face centered cubic) (111)-oriented Co/Ni interface (see Daalderop et al., Phys. Rev. Lett., 68, 682 (1992)). Buffer layers and/or seed layers are typically needed to promote a smooth and better FCC(111)-oriented growth in the Co/Ni multilayers. In this regard, FIGS. 1 (a), (b) and (c) schematically illustrate configurations applied to the promotion of a FCC (111) layer structure in a PMA multilayer system.

FIG. 1(a) shows schematically a FCC (111)-oriented PMA layer grown on a buffer layer and a seed layer. FIG. 1(b) shows schematically a BCC (body centered cubic) PMA layer, such as a Fe-based PMA layer, that is grown on an MgO tunnel barrier layer. FIG. 1(c) shows schematically an FCC (111)-oriented PMA layer grown on a BCC, Fe-based PMA layer via a seed layer that creates a smooth transition between the BCC and FCC symmetries.

In this disclosure, a buffer layer (as in FIG. 1(a)) is defined as a layer that makes a smooth and flat surface to facilitate the correspondingly smooth and flat growth of subsequently deposited layers. A seed layer (as in FIGS. 1(a) and (c)), on the other hand, is defined as a layer that operates as a template to produce a certain crystal-oriented growth of the following deposited layer (such as the FCC growth in (a) and (c)). Typical buffer layers (among others) are Ta/CuN, TaN/Cu and Ru/Ta. Typical seed layers for Co/Ni multilayers are Cu, CuN and NiCr, whose crystal structure is similar to Co and/or Ni. While the focus of this disclosure is mainly on the Co/Ni material system as an important exemplar, similar PMA multilayer systems, such as (Co,Fe)/Pt, (Co, Fe)/Pd, Co/Ru, Co/Ni/Pt, and Co/Ni/Fe/Pt will also benefit from the method to be described herein.

Specifically, the methods of this disclosure are intended to address a problem confronting material combinations used in current multilayer constructions for tunneling magnetoresistive (TMR) devices that include thin MgO tunnel barrier layers interfaced with Fe containing ferromagnetic layers. The problem referred to, is that such constructions are limited in the thickness ranges within which the PMA condition can be maintained because the PMA originates at a single interface. As the magnetic layer becomes thicker, the perpendicular anisotropy field will decrease and will eventually be overcome by the demagnetizing field (see equ. (1) below). This, in turn, will result in the magnetization moving within the plane of the film. Therefore it becomes difficult to maintain good thermal stability of the magnetization direction using only the MgO interface as the source of the magnetic anisotropy. Prior arts, such as those taught by Girt et al. (U.S. Pat. No. 7,666,529) and Wang et al. (U.S. Publ. Pat. Appl. 2012/0141836), discuss aspects of interfaces between different crystalline structures, but do not treat the problem to be addressed herein.

### SUMMARY

A first object of the present disclosure is to provide a method of maintaining perpendicular to the plane magnetic anisotropy (PMA) throughout a sequence of layers, when that perpendicular to the plane magnetic anisotropy originates at interlayer interfaces.

A second object of the present disclosure is to provide such a method that is specifically exemplified by its advantageous application to interfaces between MgO and Fe-containing ferromagnetic materials, but which is also applicable to other interlayer interfaces.

A third object of the present disclosure is to provide such a method that is applicable to an MgO interface with a Fe-containing ferromagnetic layer which is part of a PMA multilayer system such as Co/Ni layered systems.

A fourth object of the present disclosure is to provide such a method that is applicable to an MgO interface with a Fe-containing ferromagnetic layer which is part of a PMA multilayer system such as (Co,Fe)/Pt, (Co, Fe)/Pd, Co/Ru, Co/Ni/Pt, and Co/Ni/Fe/Pt layered systems.

A fifth object of the present disclosure is to fulfill the previous objects by means of providing advantageous coupling between layers having BCC and FCC crystal symmetry.

A sixth object of the present disclosure is to provide a method of inducing a crystal structure in a previously amorphous layer by means of a capping overlayer that acts as a template for crystal formation during an annealing process.

These objects will be met by growing PMA layers using combinations of the methods shown schematically in FIGS. 1(a), 1(b) and 1(c). With these methods, the perpendicular magnetic anisotropy will originate from both the MgO/Fe interface and the top PMA layer that is grown over that interface. The top layer is most likely an FCC(111) oriented Co/Ni multilayer construction as shown in FIG. 1(c). Furthermore, it may be more advantageous to maintain the magnetic coupling, i.e. RKKY (Ruderman-Kittel-Kasuya-Yosida long range) coupling, exchange coupling and/or dipolar coupling, between the FCC PMA layer and the BCC layer.

Unfortunately, it is challenging to find materials that can create a smooth crystalline transition from BCC to FCC crystal symmetry. Commonly used materials to achieve this purpose are Cr and its alloys. But these materials are known to deteriorate the tunnel magnetoresistance (TMR) as they diffuse into or within the vicinity of the MgO tunneling barrier layer. Therefore, in the present disclosure, it is proposed to use Mo, as well as Nb and V, to form a transition layer between BCC and FCC crystal symmetry materials. Examples of this approach are given by the following three blanket film configurations:
(#1) Si/SiO₂/Underlayer/FeCoB/MgO/FeCoB(1.2 nm)/Mo(1.0 nm)/[Co 0.23 nm/Ni 0.46 nm]×6/Ta/Capping layer. (Note, the Co thickness could be between 0.5 A and 5 A and the Ni thickness could range between 2 A and 10 A)
(#2) Si/SiO₂/Underlayer/FeCoB/MgO/FeCoB(1.2 nm)/Mo(1.2 nm)/[Co 0.23 nm/Ni 0.46 nm]×6/Ta/Capping layer. (Note, the Co thickness could be between 0.5 A and 5 A and the Ni thickness could range between 2 A and 10 A)
(#3) Si/SiO₂/Underlayer/FeCoB/MgO/FeCoB(1.2 nm)/Mo(1.4 nm)/[Co 0.23 nm/Ni 0.46 nm]×6/Ta/Capping layer. (Note, the Co thickness could be between 0.5 A and 5 A and the Ni thickness could range between 2 A and 10 A)

These three configurations, differing as shown in the thickness of the Mo transition layer, are annealed for 30 minutes at 400° C. following deposition and then measured in a polar Kerr magnetometer with the applied magnetic field perpendicular to the plane of the layers. The results indicate that the objects set forth above have been met and the details will now be discussed below.

### BRIEF DESCRIPTION OF THE DRAWINGS

FIGS. 1(a)-1(c) are three schematic illustrations showing different methods of producing crystalline symmetry when growing PMA layers.

FIG. 2 is a schematic illustration showing the particular layered configuration corresponding to blanket film #1 and also discussed in FIG. 4.

FIG. 3 is a Kerr intensity plot vs. external magnetic field for three deposited blanket films containing Mo transition layers of different thicknesses.

FIG. 4 is a magnetoresistance curve for a patterned film corresponding to blanket film #1.

FIGS. 5(a) and 5(b) are schematic illustrations showing the application of an Mo capping layer as a template.

### DETAILED DESCRIPTION

The present disclosure provides a method for providing enhanced PMA within a layered construction when the PMA originates at an interface between a layer of MgO and an Fe-containing ferromagnetic layer and where smooth transitions between BCC and FCC crystalline symmetries are promoted by a transition layer, such as a layer of Mo.

A recent advance in the development of MRAM (magnetic random access memory) devices is the use of the high interfacial PMA originating at the interface of MgO and Fe or Fe alloy, including FeCoB, FeB, etc., used as ferromagnetic layers (see FIG. 1(b)). Similarly to the Co/Ni interface discussed above, the MgO/Fe interface provides a strong PMA source (see, Ikeda et al., Nature Mater., 9, 721 (2010)). This material combination (and its interfacial property) is very advantageous for constructing high quality MTJs (magnetic tunneling junctions) that are used for memory elements in MRAMs, because these kinds of MTJ devices typically use a thin MgO tunneling barrier layer that also provides additional spin filtering between the Fe-based ferromagnetic electrodes (Butler et al., Phys. Rev B 63,054416, (2001)). This allows TMR ratios higher than 100%. This high ratio is dependent on a good lattice match at the MgO(001)[100]/Fe(001)[110] interfaces. Since MgO has a rocksalt crystal structure and Fe has a BCC crystal structure, a lattice matching at the MgO(001)[100]/Fe(001)[110] interface with a mismatch of only a few percent can be achieved.

Unfortunately, as was mentioned briefly above, this material combination has a limitation in the thickness range within which the PMA property can be maintained, given that it arises at a single interface. As the magnetic layer becomes thicker, the PMA field will decrease and eventually be exceeded by the demagnetizing field (see equation (1) below). This will cause the magnetization of the layer to move from perpendicularity to the plane of the layer, to be within the plane of the layer. Therefore it is difficult to achieve stable perpendicularity and thermal stability using only the MgO interface as the source of the PMA. It would be desirable if the PMA and the total magnetic moment could be separately controlled to allow the thermal stability to be improved as well as other properties.

Hₖ=Kₛ/Mₛt−DMₛ (1)

Where Hₖ is the anisotropy field, Kₛ is the interfacial anisotropy energy at the MgO/Fe interface, D is the demagnetization factor, Mₛ is the magnetic moment at saturation per unit volume and t is the thickness of the magnetic layer.

A solution to the problem of maintaining good PMA that originates at a single interface is to combine the growth structures of FIGS. 1(a) and 1(b), where the PMA will originate from both the MgO/Fe interface and the top PMA layer that is above the interface. This top layer is most likely a FCC(111) oriented layer such as Co/Ni multilayers as shown in FIG. 1(c). Furthermore, it may be more advantageous to maintain the magnetic coupling (RKKY, exchange, dipolar) between the FCC PMA layer and the BCC layer. As mentioned above, materials such as Cr and its alloys, that are known to promote coupling between different crystal symmetries, are also prone to diffuse into the MgO layer or its vicinity, lessening its effectiveness.

Consequently, as mentioned in the summary above, we propose the use of Mo (or Nb or V), rather than Cr, as a transition layer between BCC and FCC crystal symmetry. To establish the properties of Mo, and by extension, of Nb and/or V as well, we have analyzed three multilayered film depositions of the types described below, in which the Co/Ni multilayer is formed as a six-fold repetitive Co/Ni structure, where the Co is approximately 0.23 nm in thickness and the Ni is approximately 0.46 nm in thickness, although a range of Co thickness could be between 0.5 A and 5 A and the Ni thickness could range between 2 A and 10 A:
(#1) Si/SiO₂/Underlayer/FeCoB/MgO/FeCoB(1.2 nm)/Mo(1.0 nm)/[Co 0.23 nm/Ni 0.46 nm]×6/Ta/Capping layer. (Note, the Co thickness could be between 0.5 A and 5 A and the Ni thickness could range between 2 A and 10 A)
(#2) Si/SiO₂/Underlayer/FeCoB/MgO/FeCoB(1.2 nm)/Mo(1.2 nm)/[Co 0.23 nm/Ni 0.46 nm]×6/Ta/Capping layer. (Note, the Co thickness could be between 0.5 A and 5 A and the Ni thickness could range between 2 A and 10 A)
(#3) Si/SiO₂/Underlayer/FeCoB/MgO/FeCoB(1.2 nm)/Mo(1.4 nm)/[Co 0.23 nm/Ni 0.46 nm]×6/Ta/Capping layer. (Note, the Co thickness could be between 0.5 A and 5 A and the Ni thickness could range between 2 A and 10 A)

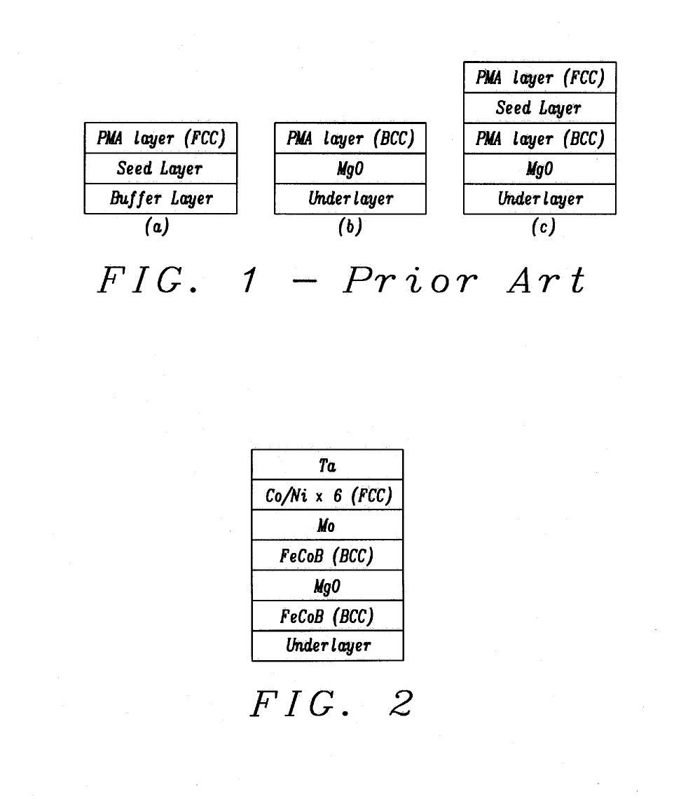

Referring to FIG. 2, there is shown schematically the layered structure corresponding to structure #1 described above. The PMA property is shown as originating at the MgO/FeCoB interface. A layer of Mo serves as a transition layer (or seed layer) to serve as an interface between the BCC structure of the FeCoB and the FCC structure of the Co/Ni multiple layers above the Mo layer. The transition layer of Mo thereby propagates the PMA property to the layers formed upon it.

The transition layers of Mo as formed within the above multi-layered structures can be formed within ferromagnetic free layers or pinned layers of, for example, MTJ sensor fabrications or MRAM elements (with appropriate MgO thicknesses), where their crystal-structure transition properties would produce enhancements of sensor performance.

These three configurations, differing as shown in the thickness of the Mo transition layer, are annealed for 30 minutes at 400° C. following deposition and then measured in a polar Kerr magnetometer with the applied magnetic field perpendicular to the plane of the layers. The results are shown in FIG. 3.

The low field loops and the high field loops (see inset) indicate that there are only perpendicular magnetized components in these samples. With the thicker Mo layer (t>=1.2 nm), the Co/Ni multilayer (here, 6 bilayers of Co/Ni) and the FeCoB layer have a separate switching field. It is found that the FeCoB switches at a lower field and the Co/Ni multilayer switches at a higher field. This may indicate that the magnetic coupling between them, most likely RKKY, becomes weaker with thicker Mo. This would imply that the PMA in the Co/Ni multilayer does not originate from the underlying PMA structure of the FeCoB via the long range RKKY coupling, but rather originates from its own interfacial PMA as a result of the adjacent Mo seed layer. With thinner Mo layers (t<=1.0 nm), the Co/Ni multilayer and the FeCoB layer switch together. These results indicate the role of the Mo layer and, therefore, show that that the Mo layer is a good seed layer for promoting PMA in Co/Ni multilayers. We conclude that the Mo provides a good template for the FCC(111) growth of the Co/Ni multilayers in spite of the presumable BCC(001) orientation of the underlying FeCoB. It should be noted that without the Mo transition layer, the same structure would not be PMA.

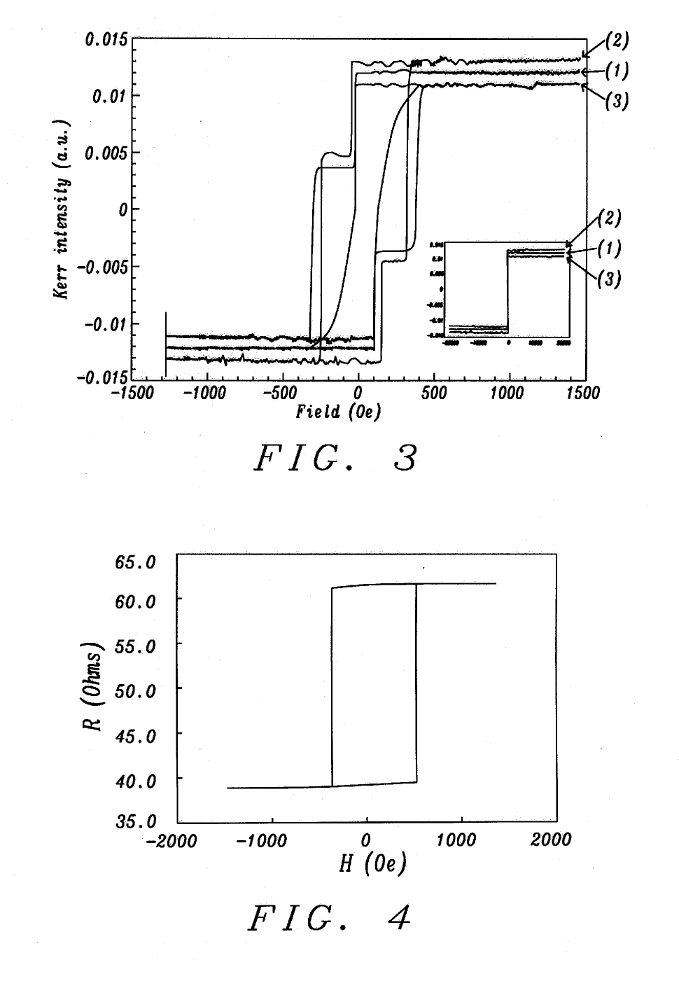

Referring now to FIG. 4, there is shown the magnetoresistance of a patterned MTJ device employing the structure of deposition #1 above. This graph clearly indicates the compatibility of Mo with MTJ devices. It should be noted that the switching shoulder of sample #1 as shown in FIG. 3 is understood as a switching that is associated with nucleation and propagation of magnetic domains in the magnetic layer. This switching shoulder is not expected in actual sub-micron/nano-sized MTJ devices for which a domain nucleation is energetically unfavorable as shown by the data of FIG. 3.

In summary, an important aspect of this disclosure relates to the crystal structure of the Mo layer. The crystal symmetry of Mo is known to be BCC at room temperature. Therefore, it naturally matches with the BCC structure of FeCoB in this study. On the other hand, Mo is reported to have a relatively good lattice matching with Ni and Co with the orientation relationship of Mo(110)/Ni(111) and Mo(110)/FCC-Co(111) (see F. Martin et al., Appl. Surf. Sci., 188, 90 (2002)). It is our belief, based on these results and the theory, that these crystal properties help to facilitate the BCC to FCC transition and, therefore, to promote the good PMA characteristics in the Co/Ni multilayer obtained in this experiment. Based on known similar properties of Nb and Vanadium (V), it is expected that those elements will provide good seed layer candidates as well.

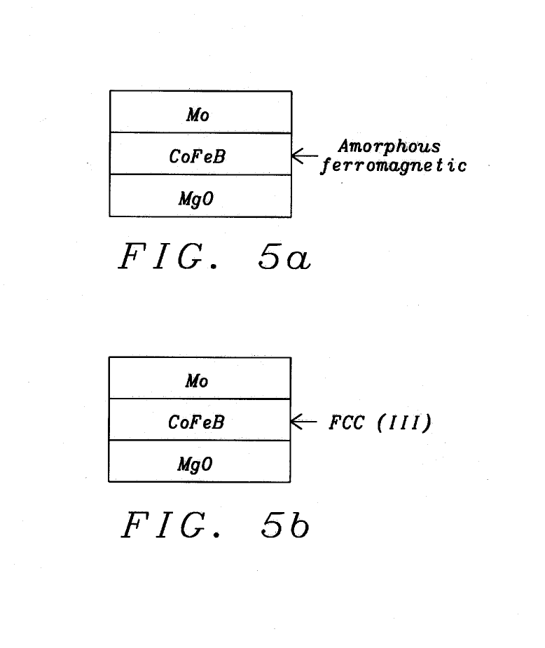

Finally, referring to FIG. 5 (a), there is shown a configuration where a layer of Mo has been used as a capping layer over a ferromagnetic layer, such as a layer of CoFeB. In this situation, the CoFeB has been formed on layer of MgO (as shown above in FIG. 1(b)). The layer of CoFeB is, at this point of the deposition process, an amorphous layer. However, after subjecting the structure of FIG. 5(a) to an annealing process, the layer of CoFeB, as shown in FIG. 5(b) is found to have acquired an FCC (111) structure. The Mo capping layer has served as a template for the crystal formation even though it is formed as a capping layer. Capping layers of V and Nb should have the same template effect under similar annealing processes.

As is finally understood by a person skilled in the art, the detailed description given above is illustrative of the present disclosure rather than limiting of the present disclosure. Revisions and modifications may be made to methods, materials, structures and dimensions employed in forming and providing a multilayer structure of differing crystal symmetries connected by a transition layer and, thereby, capable of maintaining PMA properties originating in an interface, while still forming and providing such a structure in accord with the spirit and scope of the present disclosure as defined by the appended claims.

What is claimed is:

1. A method of forming a magnetic thin film structure having PMA (perpendicular magnetic anisotropy), comprising:
providing a thin film deposition including an interface between an MgO layer and a ferromagnetic layer formed of or containing Fe, wherein a PMA originates at said interface;
forming a multilayered thin film structure over said interface, wherein said multilayered thin film structure includes material layers of different crystal symmetries;
forming a transition layer between each layer having a different crystal symmetry;
wherein said transition layer promotes a matching between said different crystal symmetries, thereby causing said PMA to be propagated within the entirety of said thin film deposition.

2. The method of claim 1 wherein the different crystal symmetries are BCC (body centered cubic) and FCC (face centered cubic).

3. The method of claim 1 wherein said transition layer is a layer of Mo.

4. The method of claim 1 wherein said transition layer is a layer of Nb or V.

5. The method of claim 3 wherein said transition layer of Mo facilitates a smooth transition between a BCC crystal symmetry and an FCC crystal symmetry.

6. The method of claim 1 wherein said material layers include layers of materials that support PMA, including layers of the materials Co/Ni, (Co,Fe)/Pt, (Co, Fe)/Pd, Co/Ru, Co/Ni/Pt, and Co/Ni/Fe/Pt.

7. The method of claim 4 wherein said transition layer of Nb or V facilitates a smooth transition between a BCC crystal symmetry and an FCC crystal symmetry.

8. The method of claim 1 further including:
providing a substrate;
forming on said substrate a pinned layer of FeCoB;
forming on said pinned layer of FeCoB a tunneling barrier layer of MgO;
forming on said tunneling barrier layer of MgO a ferromagnetic free layer of FeCoB;
forming on said ferromagnetic free layer of FeCoB a transition layer of Mo;
forming on said transition layer of Mo a repetitively multi-layered structure of Co/Ni;
forming on said repetitively multi-layered structure of Co/Ni a capping layer; then
annealing said structure.

9. The method of claim 8 wherein said free layer of FeCoB is approximately 1.2 nm in thickness.

10. The method of claim 8 wherein said transition layer of Mo is between 1.0 and 1.4 nm in thickness.

11. The method of claim 8 wherein said Co layer is of a thickness between approximately 0.5 A and 5.0 A and said Ni layer is of a thickness between approximately 2.0 A and 10 A.

12. The method of claim 8 wherein said capping layer is a layer of Ta.

13. The method of claim 8 wherein said capping layer is a layer of Mo, V or Nb and wherein said capping layer acts as a crystal structure inducing template to enhance the formation of an FCC (111) structure in layers beneath said capping layer.

14. A magnetic thin film structure having PMA (perpendicular magnetic anisotropy) comprising:
a seed layer of Mo, V or Nb or their alloys, wherein said seed layer promotes growth of FCC crystal symmetry;
a multilayer of FCC materials including a layer of at least one magnetic element having PMA, wherein said multilayer is grown on said seed layer.

15. A magnetic thin film structure having PMA (perpendicular magnetic anisotropy) comprising:
a layer having BCC (body centered cubic) crystal symmetry;
a transition layer formed of Mo, V, Nb or their alloys, formed on said BCC layer, wherein said transition layer promotes growth of FCC (face centered cubic) crystal symmetry;
a multilayer of FCC materials formed on said transition layer, wherein said multilayer includes at least one layer of magnetic material having PMA.

16. A magnetic thin film structure having PMA (perpendicular magnetic anisotropy) comprising:
an MgO/Fe interface at which PMA originates;
at least one layer having FCC (face centered cubic) crystal symmetry;
at least one layer having BCC (body centered cubic) crystal symmetry;
at least one layer that promotes a smooth transition between BCC and FCC crystal symmetry formed between said at least one layer having FCC crystal symmetry and said at least one layer having BCC crystal symmetry.

17. The magnetic thin film structure of claim 14 wherein said at least one layer having FCC crystal symmetry is a single layer or multilayer based on Co or Ni or its alloys.

18. The magnetic thin film structure of claim 14 wherein said at least one layer having BCC crystal symmetry is a layer of FeCoB.

19. The magnetic thin film structure of claim 14, wherein said material layers include layers of materials that support PMA, including layers of the materials Co/Ni, (Co,Fe)/Pt, (Co, Fe)/Pd, Co/Ru, Co/Ni/Pt, and Co/Ni/Fe/Pt.

20. A TMR (tunneling magnetoresistive) device having PMA (perpendicular magnetic anisotropy) comprising:
a multilayer of materials, including at least one layer of magnetic material having FCC (face centered cubic) crystal symmetry and at least one layer of magnetic material having BCC (body centered cubic) crystal symmetry;
a tunneling barrier layer formed as a layer of MgO within said multilayer, wherein said layer of MgO has an interface with an Fe-based ferromagnetic layer, from which interface a PMA originates;
a transition layer formed within said multilayer, wherein said transition layer promotes lattice matching between said at least one layer of magnetic material having FCC crystal symmetry and said at least one layer of magnetic material having BCC crystal symmetry;
wherein said multilayer of materials exhibits PMA.

21. The TMR device of claim 20 wherein said at least one layer of magnetic material having FCC crystal symmetry is a layer based on Co or Ni or its alloys.

22. The TMR device of claim 20 wherein said at least one layer of magnetic material having BCC crystal symmetry is a layer of FeCoB.

23. The TMR device of claim 20 wherein said transition layer is a layer of Mo, Nb or V.

24. The TMR device of claim 20 formed as a ferromagnetic free layer of a sensor element.

25. The TMR device of claim 20 formed as a ferromagnetic free layer of an MRAM element.

26. The TMR device of claim 20 formed as a pinned layer of a sensor element.

27. The TMR device of claim 20 formed as a pinned layer of an MRAM element.

28. The TMR device of claim 20 further comprising:
a substrate;
a pinned layer of FeCoB formed on said substrate;
a tunneling barrier layer of MgO formed on said pinned layer of FeCoB;
a ferromagnetic free layer of FeCoB formed on said tunneling barrier layer of MgO;
a transition layer of Mo formed on said ferromagnetic free layer of FeCoB
a repetitively multi-layered structure of Co/Ni formed on said transition layer of Mo;
a capping layer formed on said repetitively multi-layered structure of Co/Ni.

29. The TMR device of claim 28 wherein said free layer of FeCoB is approximately 1.2 nm in thickness.

30. The TMR device of claim 28 wherein said transition layer of Mo is between 1.0 and 1.4 nm in thickness.

31. The TMR device of claim 28 wherein said Co layer is of a thickness between approximately 0.5 A and 5.0 A and said Ni layer is of a thickness between approximately 2.0 A and 10 A.

32. The device of claim 28 wherein said capping layer is a layer of Ta.

33. The device of claim 28 wherein said capping layer is a layer of Mo, V or Nb that serves as a crystal growth-enhancing template for said ferromagnetic layers beneath said capping layer.
